(19) United States
(12) Patent Application Publication
(10) Pub. No.: US 2024/0388295 A1
(43) Pub. Date: Nov. 21, 2024

(54) VOLTAGE CONVERSION CIRCUIT AND CHIP

(71) Applicant: SHANGHAI IC R&D CENTER CO., LTD., Shanghai (CN)

(72) Inventors: Huijie YAN, Shanghai (CN); Xi ZENG, Shanghai (CN)

(73) Assignee: SHANGHAI IC R&D CENTER CO., LTD., Shanghai (CN)

(21) Appl. No.: 18/689,869

(22) PCT Filed: Dec. 31, 2021
(86) PCT No.: PCT/CN2021/143850

§ 371 Date: Mar. 7, 2024

(30) Foreign Application Priority Data
Sep. 7, 2021 (CN) 202111045893.8

(51) Int. Cl. H03K 19/0185; H03K 19/00; H03K 19/017

(52) U.S. Cl. CPC H03K 19/018521; H03K 19/0013; H03K 19/017

(57) ABSTRACT

The present disclosure provides a voltage conversion circuit and a chip. The voltage conversion circuit includes a first PMOS transistor, a second PMOS transistor, a third PMOS transistor and a fourth PMOS transistor, a first NMOS transistor, a second NMOS transistor, a third NMOS transistor, a fourth NMOS transistor, and a phase inverter; the source of the first PMOS transistor is connected to an I/O power supply, the drain thereof is connected with a first node, and the gate thereof is connected with a second node; the drain of the first NMOS transistor is connected with the first node, the source thereof is grounded, and the gate thereof is connected to an input signal.

### CROSS-REFERENCE TO RELATED APPLICATIONS

This application claims priority to Chinese Patent Application No. 202111045893.8, filed on Sep. 7, 2021, which is hereby incorporated by reference in its entirety.

### BACKGROUND

### Technical Field

The present invention relates to the technical field of integrated circuits, and in particular, to a voltage conversion circuit and a chip.

### Description of Related Art

An integrated circuit usually includes an I/O circuit and a core circuit to realize bidirectional data transmission. FIG. 1 is a commonly used voltage conversion circuit, where a supply voltage of an I/O power supply is VDDIO and a supply voltage of a core power supply is VDDC. It is required that the voltage conversion circuit (level shifter) converts a logic signal from 0˜VDDC to 0˜VDDIO. At present, a single VDDIO cannot meet requirement; or the voltage conversion circuit works under different VDDIOs, but it cannot reach an output speed as working under the single VDDIO.

As shown in FIG. 1, when VDDIO is greatly reduced or increased, high/low level cannot be output normally. In a practical application, there is voltage fluctuation in power supply, which makes output stability of pull-down NMOS and pull-up PMOS worse and failure probability higher.

FIG. 2 is a current mirror structure circuit. When an input signal is at a high level (VDDC), N1 and P1 are turned on at the same time, forming a direct path between VDDIO and the ground and resulting in a very large leakage current, which is contrary to a goal of low power consumption and is not suitable for a function of continuous voltage conversion.

### SUMMARY

The present invention provides a voltage conversion circuit and a chip, to solve technical problems that an existing voltage conversion circuit has slow output speed and high power consumption, and cannot meet an output requirement of a wide VDDIO range.

In view of the above, the present invention provides a voltage conversion circuit, including a first PMOS transistor, a second PMOS transistor, a third PMOS transistor and a fourth PMOS transistor, a first NMOS transistor, a second NMOS transistor, a third NMOS transistor, a fourth NMOS transistor and a phase inverter; the source of the first PMOS transistor is connected to an I/O power supply, the drain of the first PMOS transistor is connected with a first node, and the gate of the first PMOS transistor is connected with a second node; the drain of the first NMOS transistor is connected with the first node, the source of the first NMOS transistor is grounded, and the gate of first NMOS transistor is connected to an input signal; the source of the second PMOS transistor is connected to the I/O power supply, the drain of the second PMOS transistor is connected with the second node, and the gate of the second PMOS transistor is connected with the first node; the drain of the second NMOS transistor is connected with the second node, the source of the second NMOS transistor is grounded, the gate of the second NMOS transistor is connected with an output terminal of the phase inverter, and an input terminal of the phase inverter is connected to the input signal; the source of the third PMOS transistor is connected to an external power supply, the drain of the third PMOS transistor is connected with the third node, and the gate of the third PMOS transistor is connected to the input signal; the drain of the third NMOS transistor is connected with the third node, the source of the third NMOS transistor is connected with the first node, and the gate of the third NMOS transistor is connected with the second node; the source of the fourth PMOS transistor is connected to the external power supply, the drain of the fourth

NMOS transistor is connected with a fourth node, and the gate of the fourth NMOS transistor is connected with the output terminal of the phase inverter; the drain of the fourth NMOS transistor is connected with the fourth node, the source of the fourth NMOS transistor is connected with the second node, and the gate of the fourth NMOS transistor is connected with the first node. Optionally, a voltage of the I/O power supply is VDDIO, and a range of the VDDIO is 1.6V˜3.6V.

Optionally, the external power supply is a core power supply of a core circuit.

Optionally, a voltage of the external power supply is VDDC1, and V-rated≥VDDC1≥|Vthp|, where V-rated is a rated working voltage of the third PMOS transistor and the fourth PMOS transistor, and Vthp is a threshold voltage of the third PMOS transistor and the fourth PMOS transistor.

Optionally, the first PMOS transistor, the second PMOS transistor, the third PMOS transistor, the fourth PMOS transistor, the first NMOS transistor, the second NMOS transistor, the third NMOS transistor, and the fourth NMOS transistor are thick gate oxide MOS transistors.

Optionally, the third PMOS transistor and the fourth PMOS transistor are thin gate oxide MOS transistors.

Optionally, the first node or the second node is an output terminal of the voltage conversion circuit.

The present invention also provides a chip including a core circuit and the voltage conversion circuit according to any one of the above, and an output terminal of the core circuit is connected with an input terminal of the voltage conversion circuit.

The voltage conversion circuit and the chip provided by the present invention can meet an output requirement of a wide VDDIO range, and have high output speed and low power consumption. When converting from a low level VDDC to a high level VDDIO, the voltage conversion circuit can resist a failure caused by VDDC fluctuation and possess good anti-interference ability.

### BRIEF DESCRIPTION OF THE DRAWINGS

FIG. 1 is a schematic structural diagram of a voltage conversion circuit in the prior art.

FIG. 2 is a schematic structural diagram of a voltage conversion circuit in the prior art.

FIG. 3 is a schematic structural diagram of a voltage conversion circuit provided by an embodiment of the present invention.

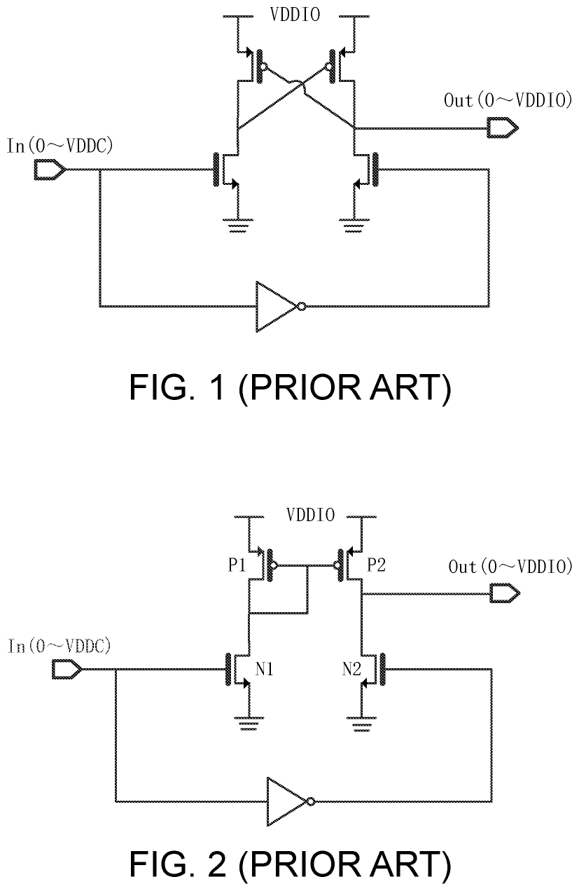

### REFERENCE NUMBERS ARE EXPLAINED AS FOLLOWS

first PMOS transistor—P1, second PMOS transistor—P2, third PMOS transistor—P3, fourth PMOS transistor—P4, first NMOS transistor—N1, second NMOS transistor—N2, third NMOS transistor—N3, fourth NMOS transistor—N4, first node—Outn, second node—Out, third node—A and fourth node—B.

### DESCRIPTION OF THE EMBODIMENTS

In order to make the purpose, advantages and characteristics of the present invention more clear, a voltage conversion circuit and a chip proposed by the present invention will be further described in detail with reference to the accompanying drawings. It should be noted that all the drawings are in a very simplified form and use inaccurate proportions, which are only used for the purpose of conveniently and clearly illustrating embodiments of the present invention.

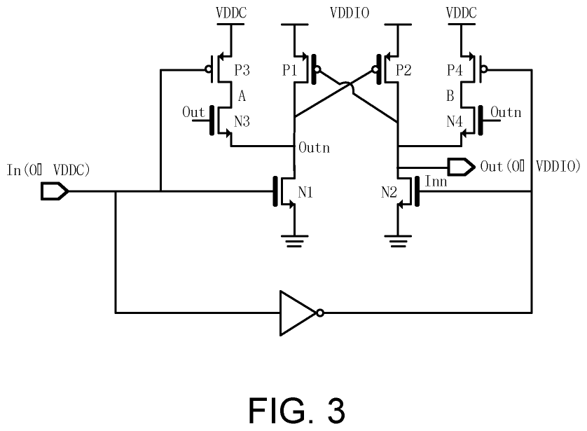

As shown in FIG. 3, an embodiment provides a voltage conversion circuit which includes a first PMOS transistor P1, a second PMOS transistor P2, a third PMOS transistor P3, a fourth PMOS transistor P4, a first NMOS transistor N1, a second NMOS transistor N2, a third NMOS transistor N3, a fourth NMOS transistor N4 and a phase inverter. The source of the first PMOS transistor P1 is connected to an I/O power supply, the drain of the first PMOS transistor P1 is connected with the first node Outn, and the gate of the first PMOS transistor P1 is connected with a second node Out. The drain of the first NMOS transistor N1 is connected with the first node Outn, the source of the first NMOS transistor N1 is grounded, and the gate of the first NMOS transistor N1 is connected to an input signal.

The source of the second PMOS transistor P2 is connected to the I/O power supply, the drain of the second PMOS transistor P2 is connected with the second node Out, and the gate of the second PMOS transistor P2 is connected with the first node Outn.

The drain of the second NMOS transistor N2 is connected with the second node Out, the source of the second NMOS transistor N2 is grounded, the gate of the second NMOS transistor N2 is connected with an output terminal of the phase inverter, and the input terminal of the phase inverter is connected to the input signal.

The source of the third PMOS transistor P3 is connected to an external power supply, the drain of the third PMOS transistor P3 is connected with a third node A, and the gate of the third PMOS transistor P3 is connected to the input signal.

The drain of the third NMOS transistor N3 is connected with the third node A, the source of the third NMOS transistor N3 is connected with the first node Outn, and the gate of the third NMOS transistor N3 is connected with the second node Out.

The source of the fourth PMOS transistor P4 is connected to an external power supply, the drain of the fourth PMOS transistor P4 is connected with a fourth node B, and the gate of the fourth PMOS transistor P4 is connected with the output terminal of the phase inverter.

The drain of the fourth NMOS transistor N4 is connected with the fourth node B, the source of the fourth NMOS transistor N4 is connected with the second node Out, and the gate of the fourth NMOS transistor N4 is connected with the first node Outn.

The structure shown in FIG. 3 includes a group of MOS devices (N1, N2, P1, P2) with a cross-coupled structure (cross coupled structure) and a group of dynamically pre-charged input follower MOS devices (N3, N4, P3 and P4). In an embodiment, some components are denoted by reference numbers, for example, N1 denotes the first NMOS transistor N1.

The input signal In (0˜VDDC) and the reverse signal Inn are used to control turn-on and turn-off of a pull-down NMOS (N1/N2), and both require a voltage conversion. When the input signal In is at a high level VDDC, the reverse signal Inn is at a low level 0, N1 is turned on, and N2 is turned off. N1 pulls down the first node Outn to a low potential (0V), and turns on P2, and P2 pulls up the second node Out to a high potential (VDDIO), thus realizing the voltage conversion between VDDC and VDDIO. When the input signal In is flipped to a low level of 0, N1 is turned off and N2 is turned on. At the flip moment, P2 has not been turned off, and P2 and N2 are turned on at the same time to form a direct path between VDDIO and the ground. Due to a contention between P2 and N2 (contention between P2 and N2), the second node Out cannot be pulled down to the low potential immediately while P3 has been turned on and the third node A is charged by VDDC. The temporary high potential of the second node Out keeps N3 on, and begins to charge the first node Outn, raising a gate voltage of P2. When P2 fails the contention with N2, the second node Out is quickly pulled down to the low potential, and N3 is turned off and stops charging the first node Outn. The cross-coupled structure realizes a normal output of a flipped signal.

When the signal is flipped again, the cross-coupled structure repeats the above-mentioned similar actions again. The input signal In and the reverse signal Inn are flipped between 0˜VDDC, and the first node Outn and the second node Out are also flipped between 0˜VDDIO thereto, thus realizing the voltage conversion output of the signal from the core circuit to the outside.

Optionally, the voltage of the I/O power supply is VDDIO, and the range of VDDIO is 1.6V˜3.6V. It is verified by experiments that the voltage conversion circuit provided by this implementation can be applied to a wide voltage range of 1.6V˜3.6V.

Optionally, since the core circuit is equipped with a core power supply, and the voltage of the core power supply is VDDC, the core power supply can be used as an external power supply.

Optionally, the voltage of the external power supply is VDDC1, and V-rated≥VDDC1≥|Vthp|, where V-rated is a rated working voltage of the third PMOS transistor and the fourth PMOS transistor, and Vthp is a threshold voltage of the third PMOS transistor and the fourth PMOS transistor.

Referring to FIG. 3, the external power supply for the pull-up transistors P3 and P4 can be set separately. For example, a power supply with the voltage of VDDC1 is set instead of using the core power supply, that is, VDDC can be replaced with VDDC1. VDDC1 should be less than or equal to the V-rated to ensure that the source and the drain of P3 and the source and the drain of P4 will not bear a voltage exceeding their rated working capacity. In order to ensure the normal turn-on of P3 and P4, VGS≤Vthp, where VGS is a voltage difference between the gate and the source of P3 and a voltage difference between the gate and the source of P4. When P3 and P4 are turned on, it can be considered that the voltage at the gates of P3 and P4 is 0 at this time, thus VGS=0−VDDC1≤Vthp, that is, VDDC1≥−Vthp, that is, VDDC1≥|Vthp|.

Optionally, P1, P2, P3, P4, N1, N2, N3 and N4 are thick gate oxide MOS transistors, which can prevent MOS transistors from being burned by high voltage and improve reliability of the circuit.

Optionally, P3 and P4 are thin gate oxide MOS transistors. The voltage at the gates of P3 and P4 is VDDC, and P3 and P4 are thin gate oxide devices, so the turn-on speed is faster and the pre-charging speed of each node is accelerated. The second node Out and the first node Outn are directly controlled by the input signal In and the reverse signal Inn, respectively, that is, N3 and N4 are indirectly controlled by Inn and In, respectively, and P3 and P4 are always turned on before N3 and N4. Before Outn and Out rise to VDDIO, A and B have been raised to VDDC1 by VDDC1. The maximum voltage of A and B is VDDC1, and the minimum voltage thereof is 0. Therefore, the maximum voltage difference VDS between the source and the drain of P3 and P4 is VDDC1−0=VDDC1, and the minimum voltage difference VDS between the source and the drain of P3 and P4 is VDDC1−VDDC1=0, that is, the variation range of VDS is 0˜VDDC1. When the voltage of VDDC1 is limited to be less than or equal to the rated working voltage of P3 and P4, electrodes of P3 and P4 will not bear the voltage exceeding the rated working capacity of P3 and P4, so as to ensure VDS≤V-rated.

Optionally, the first node Outn or the second node Out is the output terminal of the voltage conversion circuit. In a practical application of the voltage conversion circuit, the first node Outn or the second node Out can be selected as the output of the voltage conversion circuit according to a requirement of a later-stage circuit.

Based on the same technical concept as the voltage conversion circuit mentioned above, an embodiment also provides a chip which includes a core circuit and the voltage conversion circuit mentioned in any one of the above, and the output terminal of the core circuit is connected with the input terminal of the voltage conversion circuit, that is, the output signal of the core circuit serves as the input signal of the voltage conversion circuit.

To sum up, the voltage conversion circuit and the chip provided by the embodiment can meet an output requirement of a wide VDDIO range, and have high output speed and low power consumption. When converting from a low level VDDC to a high level VDDIO, the voltage conversion circuit can resist a failure caused by VDDC fluctuation and possess a good anti-interference ability.

The above description is only a description of a preferred embodiment of the present invention, and does not limit the scope of the present invention in any way. Any change and modification made by those of ordinary skill in the art according to the above disclosure belong to the protection scope of the present invention.

1. A voltage conversion circuit, comprising a first PMOS transistor, a second PMOS transistor, a third PMOS transistor, a fourth PMOS transistor, a first NMOS transistor, a second NMOS transistor, a third NMOS transistor, a fourth NMOS transistor and a phase inverter, wherein
a source of the first PMOS transistor is connected to an I/O power supply, a drain of the first PMOS transistor is connected with a first node, and a gate of the first PMOS transistor is connected with a second node,
a drain of the first NMOS transistor is connected with the first node, a source of the first NMOS transistor is grounded, and a gate of first NMOS transistor is connected to an input signal,
a source of the second PMOS transistor is connected to the I/O power supply, a drain of the second PMOS transistor is connected with the second node, and a gate of the second PMOS transistor is connected with the first node,
a drain of the second NMOS transistor is connected with the second node, a source of the second NMOS transistor is grounded, a gate of the second NMOS transistor is connected with an output terminal of the phase inverter, and an input terminal of the phase inverter is connected to the input signal,
a source of the third PMOS transistor is connected to an external power supply, a drain of the third PMOS transistor is connected with a third node, and a gate of the third PMOS transistor is connected to the input signal,
a drain of the third NMOS transistor is connected with the third node, a source of the third NMOS transistor is connected with the first node, and a gate of the third NMOS transistor is connected with the second node,
a source of the fourth PMOS transistor is connected to the external power supply, a drain of the fourth NMOS transistor is connected with a fourth node, and a gate of the fourth NMOS transistor is connected with the output terminal of the phase inverter,
a drain of the fourth NMOS transistor is connected with the fourth node, a source of the fourth NMOS transistor is connected with the second node, and a gate of the fourth NMOS transistor is connected with the first node.

2. The voltage conversion circuit according to claim 1, wherein a voltage of the I/O power supply is VDDIO, and a range of the VDDIO voltage level is 1.6V˜3.6V.

3. The voltage conversion circuit according to claim 1, wherein the external power supply is a core power supply of a core circuit.

4. The voltage conversion circuit according to claim 1, wherein a voltage of the external power supply is VDDC1, and V-rated≥VDDC1≥|Vthp|, wherein the V-rated is a rated working voltage of the third PMOS transistor and the fourth PMOS transistor, and the Vthp is a threshold voltage of the third PMOS transistor and the fourth PMOS transistor.

5. The voltage conversion circuit according to claim 1, wherein the first PMOS transistor, the second PMOS transistor, the third PMOS transistor, the fourth PMOS transistor, the first NMOS transistor, the second NMOS transistor, the third NMOS transistor and the fourth NMOS transistor are thick gate oxide MOS transistors.

6. The voltage conversion circuit according to claim 1, wherein the third PMOS transistor and the fourth PMOS transistor are thin gate oxide MOS transistors.

7. The voltage conversion circuit according to claim 1, wherein the first node or the second node is an output terminal of the voltage conversion circuit.

8. A chip, comprising a core circuit and a voltage conversion circuit, wherein the voltage conversion circuit comprises a first PMOS transistor, a second PMOS transistor, a third PMOS transistor, a fourth PMOS transistor, a first NMOS transistor, a second NMOS transistor, a third NMOS transistor, a fourth NMOS transistor and a phase inverter,
wherein a source of the first PMOS transistor is connected to an I/O power supply, a drain of the first PMOS transistor is connected with a first node, and a gate of the first PMOS transistor is connected with a second node,
wherein a drain of the first NMOS transistor is connected with the first node, a source of the first NMOS transistor is grounded, and a gate of first NMOS transistor is connected to an input signal,
wherein a source of the second PMOS transistor is connected to the I/O power supply, a drain of the second PMOS transistor is connected with the second node, and a gate of the second PMOS transistor is connected with the first node,
wherein a drain of the second NMOS transistor is connected with the second node, a source of the second NMOS transistor is grounded, a gate of the second NMOS transistor is connected with an output terminal of the phase inverter, and an input terminal of the phase inverter is connected to the input signal,
wherein a source of the third PMOS transistor is connected to an external power supply, a drain of the third PMOS transistor is connected with a third node, and a gate of the third PMOS transistor is connected to the input signal,
wherein a drain of the third NMOS transistor is connected with the third node, a source of the third NMOS transistor is connected with the first node, and a gate of the third NMOS transistor is connected with the second node,
wherein a source of the fourth PMOS transistor is connected to the external power supply, a drain of the fourth NMOS transistor is connected with a fourth node, and a gate of the fourth NMOS transistor is connected with the output terminal of the phase inverter,
wherein a drain of the fourth NMOS transistor is connected with the fourth node, a source of the fourth NMOS transistor is connected with the second node, and a gate of the fourth NMOS transistor is connected with the first node,
wherein an output terminal of the core circuit is connected with an input terminal of the voltage conversion circuit.

9. The chip according to claim 8, wherein a voltage of the I/O power supply is VDDIO, and a range of the VDDIO voltage level is 1.6V˜3.6V.

10. The chip according to claim 8, wherein the external power supply is a core power supply of the core circuit.

11. The chip according to claim 8, wherein a voltage of the external power supply is VDDC1, and V-rated≥VDDC1≥|Vthp|, wherein the V-rated is a rated working voltage of the third PMOS transistor and the fourth PMOS transistor, and the Vthp is a threshold voltage of the third PMOS transistor and the fourth PMOS transistor.

12. The chip according to claim 8, wherein the first PMOS transistor, the second PMOS transistor, the third PMOS transistor, the fourth PMOS transistor, the first NMOS transistor, the second NMOS transistor, the third NMOS transistor and the fourth NMOS transistor are thick gate oxide MOS transistors.

13. The chip according to claim 8, wherein the third PMOS transistor and the fourth PMOS transistor are thin gate oxide MOS transistors.

14. The chip according to claim 8, wherein the first node or the second node is an output terminal of the voltage conversion circuit.
